(19) United States
(12) Patent Application Publication
(10) Pub. No.: US 2013/0249096 A1
(43) Pub. Date: Sep. 26, 2013

(54) THROUGH SILICON VIA FILLING

(71) Applicants: Mona Eissa, Allen, TX (US); Nicholas S. Dellas, Dallas, TX (US); Brian E. Goodlin, Plano, TX (US)

(72) Inventors: Mona Eissa, Allen, TX (US); Nicholas S. Dellas, Dallas, TX (US); Brian E. Goodlin, Plano, TX (US)

(73) Assignee: TEXAS INSTRUMENTS INCORPORATED, Dallas, TX (US)

(21) Appl. No.: 13/591,026

(22) Filed: Aug. 21, 2012

Related U.S. Application Data
(60) Provisional application No. 61/614,845, filed on Mar. 23, 2012.

(51) Int. Cl. H01L 23/532; H01L 21/768

(52) U.S. Cl. 257/751; 438/653; 438/667; 257/E21.577; 257/E21.584; 257/E23.16

(57) ABSTRACT

A method for forming a through silicon via (TSV) in a substrate comprising: depositing a seed layer in a TSV hole; and annealing the seed layer.

This patent application claims priority to U.S. provisional patent application 61/614,845 filed on Mar. 23, 2012 for COPPER ELECTROCHEMICAL DEPOSITION PROCESS (ECD) FOR THROUGH SILICON VIAS (TSV) which is incorporated by reference for all that is disclosed therein.

### BACKGROUND

A through-silicon via (TSV) is a vertical electrical connection passing completely through a silicon wafer or die. TSV technology is important in creating 3D packages and 3D integrated circuits (IC). It provides interconnection of vertically aligned electronic devices through internal wiring that significantly reduces complexity and overall dimensions of a multi-chip electronic circuit.

A typical TSV process includes formation of TSV holes and deposition of a diffusion barrier layer and a conductive seed layer. A conductive material is then electroplated into TSV holes. Copper is typically used as the conductive material as it supports high current densities experienced at complex integration, such as 3D packages and 3D integrated circuits, and increased device speed. Furthermore, copper has good thermal conductivity and is available in a highly pure state.

TSV holes typically have high aspect ratios and depositing copper into such structures can be challenging. CVD deposition of copper requires complex and expensive precursors, while PVD deposition often results in voids and limited step coverage. Electroplating is a more common method of depositing copper into TSV structures; however, electroplating also presents a set of challenges because of the TSV's large size and high aspect ratio.

Typically, an electroplating solution for TSVs includes copper sulfate as a source of copper ions, sulfuric acid for controlling conductivity, copper chloride for nucleation of suppressor molecules, and several other additives. Methodology and apparatus for filling TSV holes are disclosed in U.S. Pat. No. 8,043,967 for PROCESS FOR THROUGH SILICON VIA FILING of Reid et al., issued Oct. 25, 2011, which is hereby incorporated by reference for all that is disclosed therein.

### SUMMARY

A high volume copper electroplating method in through silicon via (TSV) holes having large sizes and high aspect ratios is described.

Applicants have discovered that two modifications of prior used processes can significantly reduce TSV plating/filing times and can also improve the quality of TSV's that are produced. The first modification is to seed layer formation. According to applicants' process the seed layer is annealed prior to plating of the TSV hole as described below. The second modification is to the rotation rate of the substrate during the plating period. According to applicants' process the rotation rate is increased substantially as described below.

Prior to electroplating a TSV hole, a copper seed layer is applied to the interior wall of the hole and surrounding field. The seed layer in some embodiments is applied over a barrier layer. The substrate containing the TSV is placed in an annealing furnace after the seed layer is applied. The seed layer is annealed at a temperature of at least 150° C. for at least 30 minutes. In one embodiment the annealing temperature is at least about 100° C. and the annealing period is at least about 30 minutes. Annealing of the seed layer produces a seed layer surface that can be fill/plated with few or any voids and reduced overburden and at a rate that increases product throughput by about a factor of 6 as compared to a seed layer that has not been annealed.

The plating solution for copper deposition inside the TSV holes may have a relatively low concentration of sulfuric acid and high concentration of copper ions. TSV deposition processes may benefit from faster copper migration through the plating solution and, in particular, to the bottom of the TSV hole. Bath species must rely on diffusion and migration to reach the via bottom and these are relatively slow processes. The species diffusion/migration times are impacted by, solution conductivity (bath and pre-wet), current density, solution temperature and species concentrations. Species that are transported to via bottom first are protons, accelerator B, Cl, & Cu. Species that are transported to the via bottom much later are believed to be the large molecular weight leveler compound, and suppressor molecules. The solution may be maintained at temperatures between about 22° C. to 80° C. Copper is electroplated into the TSV hole in a substantially void free manner and, in certain embodiments, over a period of less than about 17 minutes. Applicants have discovered that a relatively fast rotation speed improves the plating process. In some embodiments the speed is between about 50 rpm and 100 rpm. In one embodiment the rotation speed is at least about 100 rpm.

In certain embodiments, the method includes plating a TSV of at least 10 micrometers in diameter and at least 20 micrometers in depth. In some embodiments, a TSV may be between about 10 and 80 micrometers in diameter and between about 20 and 200 micrometers in depth. The TSV holes may have aspect ratio of between about 4:1 to about 15:1.

The method may include contacting a structure having a TSV hole with a plating solution having a pH between about 0 and 5 and copper ions in a concentration of at least about 50 grams per liter. In a more specific embodiment, the plating solution has a pH between about 0 and 3. In one embodiment, the solution contains between about 50 grams per liter and 200 grams per liter of copper ions. In a more specific embodiment, the concentration of copper ions in the plating solution is between about 60 grams per liter and 100 grams per liter. The source of the copper ions may be copper methane sulfonate, copper sulfate, copper pyrophosphate, copper propanesulfonate, or a combination thereof.

In one specific embodiment, the plating solution has a temperature of about 25° C. Also as indicated, the plating solution may contain very little to no chloride ions. In one embodiment, the plating solution contains chloride ions in a concentration of between 0 and 120 ppm. In one embodiment, the concentration of chloride ions may be about 70 ppm.

The current density during plating process may be between about 0.1 and 20 mA/cm² over the plating surface. In other embodiments, the current density during the plating process may be between about 0.1 and 10 mA/cm².

In one embodiment of a semiconductor processing apparatus the apparatus includes one or more electroplating baths and a controller for executing a set of instructions. The apparatus may also include a source or supply of plating solution. In certain embodiments, the plating solution has a pH between about 0 and 3 and copper ions in a concentration of at least about 50 grams per liter. The instructions may include contacting a structure having a TSV hole with the plating solution, and while contacting the structure, plating copper into the through silicon via hole to completely fill the through silicon via in a substantially void free manner and over a period of less than about 17 minutes. The apparatus may also include a temperature controller for maintaining a temperature of the plating solution at about 25° C. while plating copper into the TSV hole. The apparatus may also include an assembly for rotating the wafer at a selected rate while it is in the one or more electroplating baths. In one embodiment the selected rate is at least about 100 rpm.

These and other features and advantages of a TSV forming process will be described in more detail with reference to the figures and associated description that follows.

### BRIEF DESCRIPTION OF THE DRAWINGS

FIG. 1 is a schematic representation of a through silicon via (TSV) at various processing stages starting with TSV hole formation, followed by lining with a diffusion barrier layer and seed layer, then annealing, then electroplating, then thinning, then forming a solder bump, and then interconnecting with another TSV.

FIG. 2 is a process flow diagram illustrating several operations of TSV processing in accordance with the present invention.

FIG. 3 is a schematic representation of an electroplating apparatus.

FIG. 4 is a schematic representation of a wafer processing apparatus.

### DETAILED DESCRIPTION

In this disclosure various terms are used to describe a semiconductor processing work piece. For example, “wafer” and “substrate” are used interchangeably. The process of depositing, or plating, metal onto a conductive surface via an electrochemical reaction is referred to generally as electroplating or electrofilling.

### Through Silicon Vias

A through-silicon via (TSV) is a vertical electrical connection passing completely through a silicon wafer or a die. TSV technology may be used in 3D packages and 3D integrated circuits, sometimes collectively referred to as 3D stacking. For example, a 3D package may contain two or more integrated circuits (ICs) stacked vertically so that they occupy less space. Traditionally, stacked ICs are wired together along their edges, but such wiring increases the stack's dimensions and usually requires extra layers between the ICs. TSVs provide connections through the body of the ICs leading to smaller stacks. Similarly, a 3D single IC may be built by stacking several silicon wafers and interconnecting them vertically. Such stacks behave as a single device and can have shorter critical electrical paths leading to faster operation.

Electronic circuits using TSVs may be bonded in several ways. One method is “wafer-to-wafer”, where two or more semiconductor wafers having circuitry are aligned, bonded, and diced into 3D ICs. Each wafer may be thinned before or after bonding. The thinning process includes removal of the wafer material to expose the bottom part of the TSV. TSVs may be formed into the wafers either before bonding or else created in the stack after bonding and may pass through the silicon substrates between active layers and an external bond pad. Another method is “die-to-wafer” where only one wafer is diced and then the singled dies are aligned and bonded onto die sites of the second wafer. The third method is “die-to-die” where multiple dies are aligned and bonded. Similar to the first method, thinning and connections may be built at any stage in the last two methods.

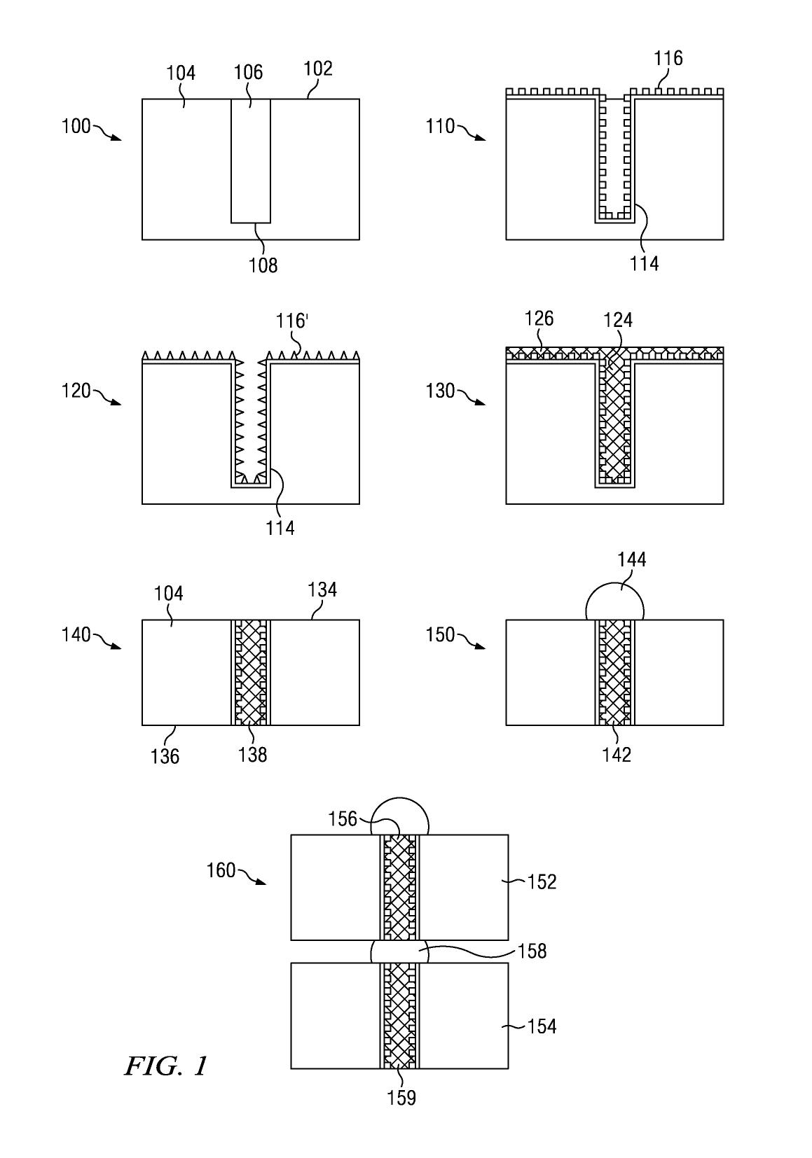

FIG. 1 is a schematic representation of a TSV at various processing stages. A TSV may be used with both dies and wafers, generally referred here as semiconductor substrate 104. Examples of the material suitable for a semiconductor substrate 104 include, but are not limited to silicon, silicon on insulator, silicon on sapphire, and gallium arsenide. It is to be understood that the term “through-silicon via” or “TSV” as used in this disclosure refers to through vias formed in a semiconductor substrate formed from any such materials, not just silicon substrates.

In a first cross-section 100, a TSV hole 106 is formed in the semiconductor substrate 104. The depth of the TSV hole 106 must be sufficient to expose the bottom 108 after the subsequent thinning operation. Typically, TSV holes may be between about 5 to 400 microns deep, however the present invention may be practiced with the TSV holes of other sizes as well. The diameter of TSV holes may vary between about 1 to 100 microns. The TSV holes typically have a very high aspect ratio, which is defined as the ratio of the TSV hole depth to the TSV hole diameter (usually at the opening). In certain embodiments, the TSV hole aspect ratio may vary between about 3:1 to 10:1. TSV size also depends on which stage of the overall 3D stacking process includes TSV formation. A TSV can be formed before (“via first”) or after (“via last”) stacking In the “via-first” configuration, the TSV may be formed before or after creating CMOS structures. In the “via-last” configuration, the TSV may be formed before or after bonding. Moreover, in both configurations, thinning may be performed before or after bonding.

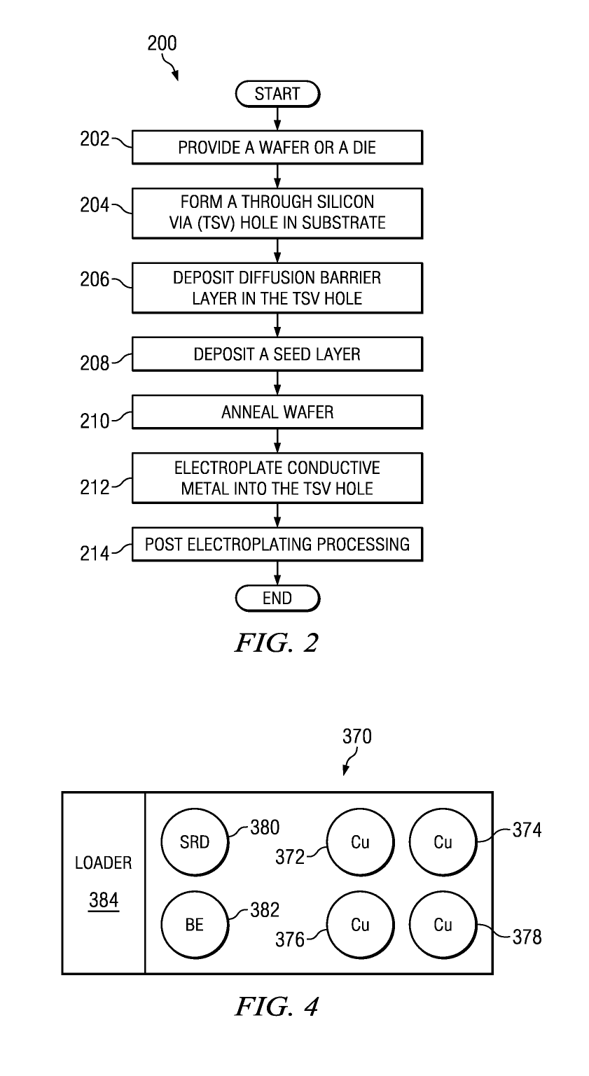

TSV holes may be formed using various methods further discussed in the context of FIG. 2. For example, TSV holes may be etched using a method optimized for high aspect ratio holes. TSV holes may have a slight positive slope and/or a taper near their openings. Such TSV profiles may improve diffusion of metal ions within TSV holes and reduce electroplating time. Returning to FIG. 1, the TSV hole 106 may be formed through a top surface 102, which is often referred to as a wafer field. The top surface 102 may be an active surface of a wafer or a die and include electronic devices. Alternatively, the TSV hole may be formed through the back surface of a wafer or a die where the circuitry is not present.

The cross-section 110 shows deposition of a diffusion barrier layer 114 and a seed layer 116 on the sides and the bottom of the TSV hole 106. Suitable materials for the diffusion barrier layer 114 include tantalum, tantalum nitride, tungsten, titanium, and titanium tungsten. In a typical embodiment, the diffusion barrier layer 114 is formed by a physical vapor deposition (PVD) process, such as sputtering, although other techniques such as chemical vapor deposition (CVD) or atomic layer deposition (ALD) may be employed. The seed layer 116 is then deposited to provide a uniform conductive surface for current passage during an electroplating operation. As with the barrier layer deposition, a PVD method may be employed for this operation, although other processes such as electroless deposition may be employed as well. Homogeneity of the seed layer 116 may be important to ensure same conductivity and uniform deposition rate. Copper may be a suitable material for the seed layer.

Cross sectional view 120 shows that the seed layer 116′ after the substrate 104 has been annealed. Annealing of the substrate 104 in one embodiment is performed in an annealing furnace at a temperature of about 200° C. and for an annealing period of about 30 minutes. The annealed seed layer 116′ has larger grains and a rougher surface than the pre-annealed seed layer 116 shown in section 110. Applicants have discovered that an annealed copper seed layer promotes proper balancing between accelerator and leveler additives in subsequent operations which promotes bottom up via plating and prevents voids. The cross sectional configuration 120 represents a unique intermediate product produced using applicants' method.

The next cross-sectional view 130 depicts conductive material 124 as deposited into the TSV hole 106. In embodiments described herein, the conductive material 124 may be electroplated copper. In a typical electroplating process, the substrate 104 is submerged into the plating solution containing metal ions. Current is then generated through the seed layer 116 causing metal ions to flow towards and deposit on the seed layer. Additional details of electroplating are discussed in the context of FIG. 2. Some of the electroplated metal may deposit on the top surface 110 forming an overburden 126. The overburden 126 is not desirable and may have to be removed in post electroplating processes, such chemical mechanical polishing, electroplanarization process, or thinning. Such overburden may be substantially reduced or eliminated by annealing as shown in cross-section 120 and described with reference to FIG. 2 below.

The next cross-section 140 illustrates the substrate 104 after post-electroplating processes to remove overburden. For example, the substrate 104 may go through edge bevel removal, electro-planarization, chemical-mechanical polishing (CMP), thinning and others. As shown, the overburden 126 is removed. The substrate 104 may be thinned forming a new bottom surface 136 and exposing the TSV end 138. A top of the substrate 104 may also be thinned forming a new top surface 134.

The next cross-section 150 shows a solder bump 144 attached to one end of the TSV 142. Examples of materials suitable for forming solder bumps include, but are not limited to, lead based solder materials (such as lead, lead/tin alloys, and others), non-lead based solder materials (such as tin/silver, tin/copper/silver, and copper alloys) and the like. Finally, illustration 160 shows a simple electronic stack where the first die 152 is interconnected with the second die 154 through a solder joint 158. The first die 152 may have the first TSV 156. Similarly, the second die 154 may have the second TSV 160. The first TSV 156, the second TSV 160, or both TSVs may have solder bumps that were used to interconnect the two TSVs and to form the solder joint 158. The stack may include additional dies and additional TSVs. For example, the second TSV may be further interconnected to another TSV in a third stack and so on. Similarly, the first die may have a plurality of TSVs some of which may be connected to TSVs of the second die, while others may be connected to TSVs of other dies. When two adjacent dies have a plurality of interconnections, the corresponding TSVs may need to be aligned. A stack including several dies may also be coupled to a heat spreader to assist in dissipation of the heat generated by the stack.

### Electroplating Process and Formation of Through Silicon Vias

FIG. 2 is a process flow diagram 200 of one method of forming TSV's. A wafer or a die is provided in operation 202. A TSV hole is then formed in a wafer or a die (block 204). The TSV holes may be formed together with circuit line paths (trenches and Damascene vias) or in a separate operation. In one embodiment, TSV holes are etched, e.g., plasma etched or reactive ion etched. The mask may be a photoresist, for example, in a “via-first” configuration, or an washable hard mask. Precise profile control (taper, tilt and sidewall roughness) is essential to ensure the quality of subsequent layer deposition and fill processes. In most cases, the TSVs are etched blind into the substrate, and then revealed by thinning in a post electroplating operation 212.

Plasma etching is an ion-enhanced chemical process, which uses RF powered plasma sources for the creation of ions and chemically reactive species. Many etching compositions employed to etch silicon include fluorine chemistry. One example employs sulfur hexafluoride together with sidewall passivation based on oxygen and/or hydrogen bromide In another example, sulfur hexafluoride plasma is used together with a polymerizing gas such as octafluorocyclobutane In yet another embodiment, TSV holes may be formed (block 204) by laser drilling or laser ablation. For example, a 355 nm wavelength UV YAG laser may be used to form vias as little as 25 micrometers in diameter. In a typical example, one hundred pulses may form an approximately 750 micrometers deep TSV.

To prevent conductive metal later deposited into the TSV hole from migrating into the surrounding dielectric layer a diffusion barrier layer may be deposited as indicated at block 206. The deposition therefore occurs before electroplating conductive metal (210). As indicated above, a diffusion barrier layer may be deposited by, for example, a physical vapor deposition process. The thickness and properties of the barrier layer depend upon the type of material employed for the barrier layer. In a typical example employing tantalum nitride, the barrier is deposited to a thickness of between about 5 and 50 nanometers on the TSV sidewalls. (In some process embodiments, the barrier deposition step is omitted.) After depositing the barrier layer, the next operation is depositing a seed layer 208 to provide uniform current deposition during subsequent electroplating; see block 210. As indicated above, the seed layer is typically PVD-formed copper, although other seed layers such as ruthenium may be employed in some embodiments. The seed layer generally should be continuous on all surfaces in the TSV structure in order to avoid localized corrosion dissolution and low local plating rates and to achieve maximum adhesion of the plated copper to the dielectric. A smooth etched surface of the TSV may facilitate deposition of continuous seed layer coverage since rough and irregular etch profiles can locally shadow some TSV surfaces during PVD deposition. In some embodiments, in order to avoid oxidation by air, the copper seed layer may be at least about 2 nm thick, but thickness as high as 200 nm is also acceptable for a large TSV structure.

Next, as illustrated by block 210 the wafer or die is heated, as in an annealing furnace, to anneal the copper seed layer. Annealing furnaces are conventional and well known in the art. The furnace annealing temperature for the wafer/die may be in a range of 50° C. to 500° C. In one embodiment the annealing furnace temperature is about 200° C. The annealing period may be from 20 minutes to 90 minutes. In one embodiment, in which the annealing furnace temperature is about 200° C., the annealing period is about 30 minutes. Annealing devices other than annealing ovens may also be used. Most commercial PVD systems, such as the Applied Materials Endura have degas chambers used to preheat the wafers prior to processing. Here this chamber may also be used to anneal the copper seed layer after deposition, before being unloaded from the tool during an annealing period of 30 seconds up to 10 minutes at annealing temperatures of about 50° C. to 500° C. In addition to conventional furnaces, rapid thermal processing (RTP) furnaces may also be used to reduce annealing time. The annealing time using an RTP furnace may be from 30 seconds up to 10 minutes at temperatures from about 50° C. to 500° C.

The wafer is then electroplated with conductive metal that fills the entire volume of the TSV holes (block 212). Voids and seams are highly undesirable. In typical embodiments, copper is used in the electroplating operation. Electroplating into TSV holes has presented challenges. In conventional plating processes, the deposition rate may be faster near the opening, where the seed layer has the greatest thickness (lowest resistance) and more metal ions are present. Moreover, deposition may take several hours to supply enough metal ions to fill an entire TSV hole. Applicants have discovered that annealing the seed layer causes the formation of larger metal grains and a rougher surface in the seed layer, which selectively effects the diffusion rate of accelerator additive and leveler additive. More specifically, it causes a high diffusion rate of accelerator additive and a low diffusion rate of leveler additive into the bottom of a TSV hole as compared to the field. This in turn causes bottom up filling of the TSV's which substantially eliminates voids in the TSV fill, minimizes overburden, decreases contamination and reduces deposition times. Applicants have discovered that by the addition of annealing step 210 that product throughput increases significantly, on the order of 6 times the throughput of an otherwise identical process, except that the annealing step is not performed and the rotation rate of the wafer is below about 50 rpm.

A typical technology for plating TSVs uses plating solution with approximately 10 gram per liter concentration of sulfuric acid. Such high acid concentration increases the conductivity of the plating solution, thereby providing for more uniform current distribution. However, a high concentration of highly mobile hydrogen ions impedes the transfer of much larger copper ions by migration. One way to express relative contribution of ions to the total deposition current flow is using transference number. The transferred number for copper ions in a typical electroplating process described above is less than 0.1. Therefore, less than 10% of the overall current flow through the solution in a TSV is carried by migration of cupric ions, while the remainder of the current is carried by other ions, such as hydrogen ions. Such low transference number is attributed to the combined effect of high mobility and concentration of hydrogen ions and much lower mobility, and often relatively low concentration of copper ions.

In one embodiment a plating solution that is substantially free from acid may be used. For example, plating solutions with pH values in the range of 2-6 may be used. In a specific embodiment, a plating solution with pH values in the range of 3-5 is used. In such compositions, more copper ions are transported to the surface than in lower pH acidic solutions.

To further facilitate copper deposition, the plating solution may also include high concentrations of copper ions. For example, the concentration of copper ions may be between about 0.8 M to 3.0 M. Such plating solutions at low pH, as specified above, may result in the copper ions transference number increasing to a level of not less than about 0.2. In one specific embodiment, the copper ions transference number may be at least about 0.4. The source of copper ions may be copper sulfate, copper methane sulfonate, copper gluconate, copper sulfamate, copper nitrate, copper phosphate, copper chloride and others. While generally higher concentrations of copper ions are desirable, these concentrations are usually limited by solubility of the copper containing salt used. For example, copper sulfate may be only dissolved up to approximately 80 grams/liter (1.25 Molar) (based on copper ion weight) in a typical plating solution formulation at room temperature.

In a more specific embodiment, the plating solution has a temperature of about 25° C. Also as indicated, the plating solution may contain very little to no chloride ions. In one embodiment, the plating solution contains chloride ions in a concentration of between 0 and 120 ppm. In a more specific embodiment, the concentration of chloride ions may be 70 ppm.

To assist in plating process one or more levelers, brighteners or accelerators, inhibitors, suppressors, enhancers, and/or surfactants may be used. Accelerators may include a polar sulfur, oxygen, or nitrogen functional group that help to increase deposition rates and may promote dense nucleation leading to films with a fine grain structure. Accelerators may be present at a low concentration level, for example 0-200 ppm. While the accelerator may produces high deposition rates within the TSV hole, the accelerator may be transported away from the substrate top surface (field region) and/or consumed by reaction with oxygen in the bulk solution. Suppressors are additives that reduce the plating rate and are usually present in the plating bath at higher concentrations, for example 5-1,000 ppm. They are generally polymeric surfactants with high molecular weight, such as polyethylene glycol (PEG). The suppressor molecules slow down the deposition rate by adsorbing on the surface and forming a barrier layer to the copper ions. Because of their large size and low diffusion rate, suppressors are less likely to reach the lower part of the TSV than the wafer field resulting in lower concentrations at the bottom of the TSV. Therefore, most suppressing effects, using conventional processes, occur on the surface of the substrate (field region), helping to reduce overburden and avoid TSV hole “closing”. Levelers are the additives whose purpose is to reduce surface roughness. They are present, if at all, in very small concentrations, such as 1-100 ppm, and their blocking effects at the surface are highly localized. As a result, levelers selectively reduce deposition mainly on the high spots allowing the low spots to level out. This behavior can also be used to enhance the plating rate of copper at the base of the TSV relative to the growth rate on the wafer field. In some cases, levelers may contain functional groups which include nitrogen atoms which exhibit a tendency to form complexes with Cu(I) ions at the wafer interface. Finally, chloride ions may be present in the plating bath at a concentration of no greater than about 300 ppm. In a specific embodiment, the chloride concentration is no greater than about 50 ppm or even no greater than about 2 ppm. As discussed above, annealing the copper seed layer produces a beneficial balancing of suppressors and levelers resulting in a number of beneficial effects.

During TSV plating the substrate may be rotated and vibrated to provide agitation around the boundary layer. Although conventionally a rotational speed of between about 20 rpm and about 50 rpm has been used, applicants have discovered that increasing the rotation speed to about 100 rpm improves the plating process. Additionally, the dissolution cycle may be performed at high current density for very short intervals leading to removal of peaks and widening of TSV openings. Furthermore, the deposition interval may be mixed with equilibration interval that allows for copper ion concentration within the TSV to equilibrate.

Returning to FIG. 2, after electro-filling conductive material into the TSV holes, the wafer may go through one or more post electrofill processing operations (block 214). If overburden is present, it will need to be removed in one of these operations. For example, chemical mechanical polishing (CMP) may be used. Other operations may include electroplanarization and/or chemical etching. Moreover, a wafer, a die, or a stack containing a TSV may be thinned to expose the bottom of the TSV to be used for other interconnections. Thinning may be carried out by any processes, for example grinding, etching, or CMP.

### The Electroplating Apparatus

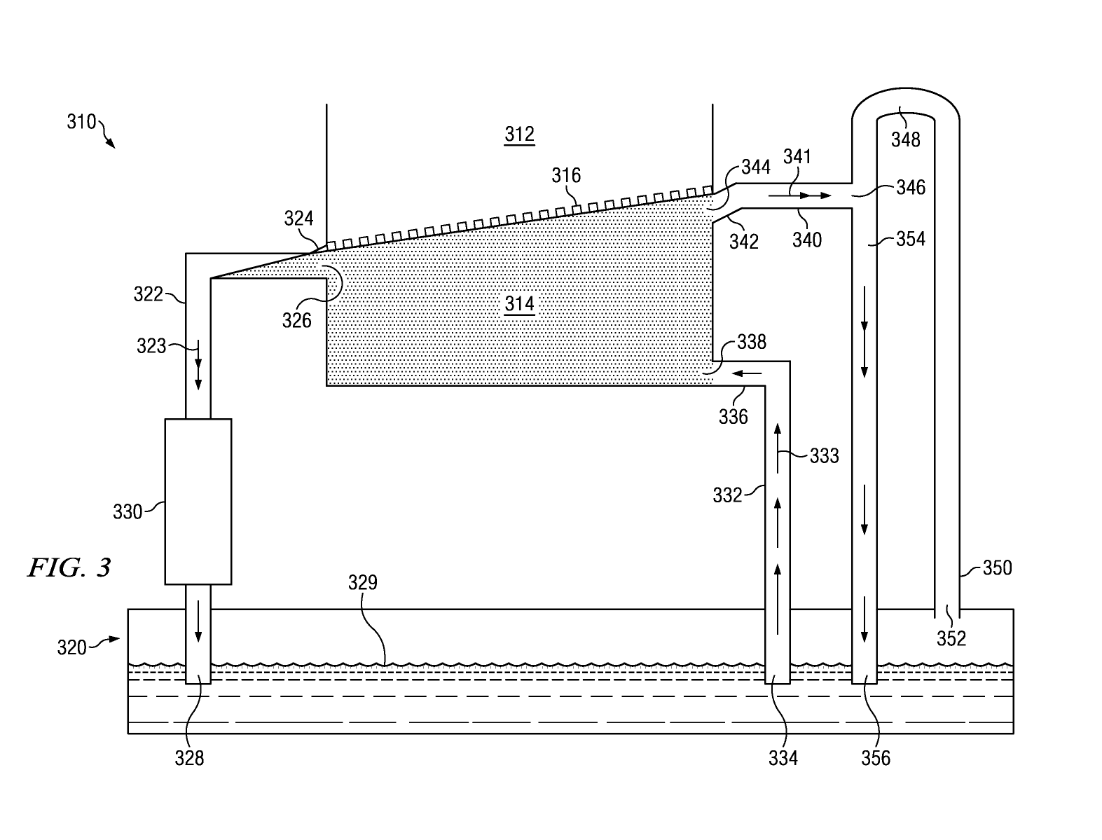

Electroplating hardware is now discussed generally to provide context for the TSV plating process described herein. The apparatus includes one or more electroplating cells in which the wafers are processed. To optimize the rates and uniformity of electroplating, additives are added to the electrolyte; however, an electrolyte with additives may react with the anode in undesirable ways. Therefore anodic and cathodic regions of the plating cell are sometimes separated by a membrane so plating solutions of different composition may be used in each region. Plating solution in the cathodic region is called catholyte; and in the anodic region, anolyte. A number of engineering designs can be used in order to introduce anolyte and catholyte into the plating apparatus. For example, the plating apparatus used may be as described in U.S. Pat. No. 8,043,967 incorporated by reference above, or may be as described below with reference to FIGS. 3 and 4, or may use other engineering designs now known or later developed.

FIG. 3 is a schematic representation of an electrochemical deposition (“ECD”) assembly 308. The ECD assembly 308 includes an ECD chamber 310 that has a catholyte side 312 and an anolyte side 314 separated by a membrane 316. The ECD chamber 310 is in fluid communication with an anolyte tank 320 that may have nitrogen purge (not shown). A first liquid conduit 322 has a first end 324 connected to an ECD chamber outlet 326 and a second end 328 positioned in tank 320 below the surface 329 of the anolyte fluid therein. Fluid flows through first conduit 322 is in direction 323. A flow control valve assembly 330 may be operably installed on first conduit 322 to control the flow rate of anolyte fluid between the anolyte side 314 of ECD chamber 310 and anolyte tank 320. A second fluid conduit 332 has a first end 334 positioned in anolyte tank 320 below the surface 319 of anolyte therein. The second conduit has a second end 336 connected to an inlet 338 at the bottom of the anolyte side 324 of ECD chamber 310. Fluid flows through the second conduit in direction 333 from anolyte tank 320 to ECD chamber 310. A third conduit 340 has a first end 342 connected to an outlet 344 at an upper portion of the anolyte side 314 of ECD chamber 310. Conduit 340 has a T-secton 346 from which a first branch line 348 and a second branch line 354 extend. The first branch line 348 has a distal end 350 connected to a vent orifice 352 at the top of anolyte tank 320 above the surface 329 of anolyte in the tank 320. The second branch line 354 has a distal end 356 which positioned in tank 320 below the surface 329 of anolyte therein. Fluid flow in the third conduit and line 354 is in direction 341 from the ECD chamber 310 to the anolyte tank 320.

The ECD chamber 310 operates as follows. A wafer is inserted into the chamber (310) with the wafer on the catholyte side (312). The wafer may be rotated inside the chamber during processing to reduce a diffuse double layer thickness. A diffuse double layer is one that builds between the surface of the wafer and the plating solution as the wafer is inserted. Copper ions from the plating solution must diffuse through this layer in order to reach the substrate to form the copper film. Electrical contact to the wafer is made in the chamber 310 so as to supply electrical current to the copper seed deposited on the wafer. As current is provided to the copper seed, a source of electrons is provided. Positively charged copper ions in the plating solution are plated on the surface of the copper seed and with time build up to form a film. This build up of copper is used to fill the TSV.

FIG. 4 is a schematic illustration of a copper plating assembly 370. The assembly 370 may include four copper plating modules 372, 374, 376, 378. The assembly 370 may also include a spin, rinse, dry module 380, a bevel etch module 382 and a loader 384. A batch of wafers can be loaded at the loader (384) and individual wafers are processed subsequently in each of the cells. Each of the copper plating cells (372, 374, 376, 378) is used to electrochemically deposit copper onto the wafer. Wafers can be processed in parallel in either of the four copper plating cells. A schematic of one of these cells 372, 374, 376, 378 is shown in FIG. 3 and described above. The bevel etch module removes plated copper from the edge of the wafer to prevent cross-contamination downline as the wafer is processed in other tools. The spin, rinse, dry module is used to clean the wafer post-processing to remove additional residue from the plating solution used in the copper plating cells (372, 374, 376, 378).

Alternative embodiments of the processes and apparatus specifically described herein will be apparent to those skilled in the art after reading this disclosure. The claims are to be construed to cover such alternative embodiments, except to the extent limited by the prior art.

What is claimed is:

1. A method for forming a through silicon via (TSV) in a substrate comprising:
depositing a seed layer in a TSV hole; and
annealing the seed layer.

2. The method of claim 1 wherein said depositing a seed layer comprises depositing a copper seed layer.

3. The method of claim 1 wherein said annealing the seed layer comprises annealing the seed layer at a temperature of at least about 100° C. for at least about 15 minutes.

4. The method of claim 3 wherein said annealing the seed layer comprises annealing the seed layer at a temperature of at least about 200° C. for at least about 30 minutes.

5. The method of claim 1 wherein said annealing the seed comprises annealing the seed in a degas chamber of a physical vapor deposition system.

6. The method of claim 5 wherein said annealing in a degas chamber comprises annealing the seed for a period of between about 30 seconds and 10 minutes.

7. The method of claim 6 wherein said annealing in a degas chamber comprises annealing the seed at a temperature of between 50° C. and 500° C.

8. The method of claim 1 wherein said annealing the seed comprises annealing the seed in a rapid thermal processing furnace.

9. The method of claim 8 wherein said annealing the seed in a rapid thermal processing furnace comprises annealing the seed for a period of between about 30 seconds and 10 minutes.

10. The method of claim 8 wherein said annealing the seed in a rapid thermal processing furnace comprises annealing the seed at a temperature of between 50° C. and 500° C.

11. The method of claim 1 further comprising:
rotating the substrate in a bath of plating solution at a rate of at least about 50 rpm.

12. The method of claim 1 further comprising:
rotating the substrate in a bath of plating solution at a rate of at least about 100 rpm.

13. The method of claim 2 comprising:
rotating the substrate in a bath of plating solution at a rate of at least about 50 rpm.

14. The method of claim 13 wherein said annealing the seed layer comprises annealing the seed layer at a temperature of at least about 200° C.

15. An intermediate product formed in a process of producing a semiconductor package with at least one TSV comprising:
a semiconductor substrate having at least one TSV hole therein; and
an annealed seed layer formed on a wall surface of said at least one TSV hole.

16. The intermediate product of claim 15 wherein said annealed seed layer is formed over a diffusion barrier layer.

17. The intermediate product of claim 15 wherein said annealed seed layer is an annealed copper seed layer.

18. A method for forming a through silicon via (TSV) in a substrate comprising:
a) forming a TSV hole in said substrate, said TSV hole having a diameter of between 10 mu and 100 mu in diameter, a depth of between 20 mu and 200 mu and an aspect ratio of between 4:1 and 15:1;
b) depositing a diffusion layer on a wall surface of said TSV hole;
c) depositing a copper seed layer on said diffusion layer;
d) annealing said seed layer at a temperature of between 50° C. and 500° C. for a predetermined period;
e) contacting said annealed copper seed layer with a plating solution having a temperature of between 22° C. and 500° C., a PH of between 0 and 6, and copper ions in a concentration of at least 50 g/L for a plating period; wherein the current density during said plating period is between about 0.1 mA/cm² and 20 mA/cm²; and
f) rotating said substrate at about 100 rpm during said plating period.

19. The method of claim 18:
wherein said annealing comprises annealing at a temperature of 200° C. for a period of at least about 30 minutes in an annealing furnace;
wherein said contacting an annealed copper seed layer with a plating solution comprises contacting the annealed copper seed layer with a plating solution having a temperature of about 25° C. and a PH of between about 3 and 5, and a copper ion concentration of between about 60 and 100 g/l, during a plating period of less than about 17 minutes.

20. The method of claim 18 wherein said annealing comprises annealing in a rapid thermal processing furnace for a period of between about 30 seconds and 10 minutes.
